(19) United States
(12) Patent Application Publication
(10) Pub. No.: US 2012/0181584 A1
(43) Pub. Date: Jul. 19, 2012

(54) Resistive Field Effect Transistor Having an Ultra-Steep Subthreshold Slope and Method for Fabricating the Same

(76) Inventors: Ru Huang, Beijing (CN); Qianqian Huang, Beijing (CN); Zhan Zhan, Beijing (CN); Yangyuan Wang, Beijing (CN)

(21) Appl. No.: 13/318,329

(22) PCT Filed: Apr. 1, 2011
(86) PCT No.: PCT/CN11/72382

§ 371 Date: Oct. 31, 2011

(30) Foreign Application Priority Data
Jan. 19, 2011 (CN) 201110021582.8

(51) Int. Cl. H01L 29/772; H01L 21/336

(52) U.S. Cl. 257/288; 438/301; 257/E29.242; 257/E21.409

(57) ABSTRACT

The invention discloses a resistive field effect transistor (ReFET) having an ultra-steep subthreshold slope, which relates to a field of field-effect-transistor logic device and circuit in CMOS ultra-large-scale-integrated circuit (ULSI). The resistive field effect transistor comprises a control gate electrode layer, a gate dielectric layer, a semiconductor substrate, a doped source region and a doped drain region, wherein the control gate is configured to adopt a stacked gate structure in which a bottom layer or a bottom electrode layer, a middle layer or a resistive material layer, and a top layer or a top electrode layer are sequentially formed. Compared with the existing methods for breaking the conventional subthreshold slope limititation, the device of the invention has a larger on-current, a lower operation voltage, and a better subthreshold feature.

### FIELD OF THE INVENTION

The invention refers to a field of a field-effect-transistor logic device and a circuit in a CMOS ultra-large-scale-integrated circuit (ULSI), particularly relates to a resistive field effect transistor (ReFET) having an ultra-steep subthreshold slope and a method for fabricating the same.

### BACKGROUND OF THE INVENTION

As a continuous down-scaling of a size of a metal-oxide-silicon filed effect transistor (MOSFET), especially when a feature size of the device enters into a nanometer regime, an adverse impact to the device such as a short channel effect becomes more obvious. A drain-induced barrier lowering (DIBL) effect and a band-to-band tunnelling effect result in an increase of an off-state leakage current, and a power consumption of the integrated circuit is increased with a reduction of a threshold voltage of the device. Moreover, since an on-current in a subthreshold region of the conventional MOSFET device is limited by diffusion mechanism, a limit value of a subthreshold slope of the device at room temperature is limited to 60 mv/dec, which causes the subthreshold leakage current increases with a reduction of the threshold voltage. In order to overcome more and more challenges faced by a MOSFET in the nanometer regime, and in order to apply the device to the ultra-low-voltage and low-power-consumption field, a device structure having a steep subthreshold slope and a method for fabricating the same obtained by using a novel turn-on mechanism has been focused under a condition of small-sized device.

As to the problem that the subthreshold slope of the MOSFET device is theoretically limited to 60 mv/dec, researchers recently have proposed some possible solutions, which mainly comprise the following three manners: a tunnelling field effect transistor (TFET), an impact ionization MOSFET (IMOS) and a suspended gate field effect transistor (SG-FET). The TEFT realizes a turn-on and a very small leakage current through controlling a band-to-band tunnelling of a reverse-biased P-I-N junction by a gate, however, since there is a limitation on a probability of a source junction tunnelling and a tunnelling area, an on-state current is small and it is not facilitated to an application onto the circuit. A patent (US2010/0140589 A1) proposed a ferroelectric tunnelling transistor, which can obtain a steeper subthreshold slope by combining a stacked ferroelectric gate layer and a band-to-band tunnelling mechanism, however, it still has a problem of small current. The IMOS is turned on by using an avalanche multiplication effect resulted from an impact ionization, which can obtain a very steep subthreshold slope (less than 10 mV/dec) and a larger current. However, the IMOS must operate under a relatively high source-drain bias voltage, and has a serious problem on device reliability, therefore it is not suitable for a practical low-voltage application. A turn-on mechanism of the SG-FET device is that, with an increase of a gate voltage, a movable metal gate electrode moves to the conventional MOSFET part under an electrostatic force, so that a channel of an inversion layer is formed and the device is turned on. In this process, due to an abrupt variation of the threshold voltage, a subthreshold slope less than 60 mV/dec can also be obtained. However, the device has also some unnegligible problems in terms of a switching speed, operation times and an integration, etc. Therefore, it is urgent to provide a device which can operate under low voltage, and has an ultra-steep subthreshold slope, a larger on-state current and a better reliability.

### SUMMARY OF THE INVENTION

A purpose of the present invention is to provide a resistive field effect transistor (ReFET) having an ultra-steep subthreshold slope and a method for fabricating the same. The structure uses a metal-insulator-metal (MIM) as a stacked gate layer, and the device has a large on-state current and a steep subthreshold slope. Furthermore, the device can operate under a low bias voltage, and can satisfy requirements on the low-voltage and low-power-consumption devices and circuit applications.

The technical solution according to the invention is described as follows:

A resistive field effect transistor (ReFET) having an ultra-steep subthreshold slope, characterized in that, it comprises: a control gate electrode layer, a gate dielectric layer, a semiconductor substrate, a doped source region and a doped drain region, wherein the control gate is configured to adopt a stacked gate structure in which a bottom layer or a bottom electrode layer, a middle layer or a resistive-switching material layer, and a top layer or a top electrode layer are sequentially formed.

The semiconductor substrate material includes Si, Ge, SiGe, GaAs or other binary or ternary compound semiconductor of II-VI, III-V and IV-IV groups, silicon on insulator (SOI), or germanium on insulator (GOI).

A material of the gate dielectric layer includes SiO₂, Si₃N₄ and high-K gate dielectric materials. A thickness of the gate dielectric layer is in a range of 1-5 nm.

The bottom electrode layer and the top electrode layer may comprise various metals such as Cu, W, TiN, Pt, Al, etc., conductive materials such as conductive metal silicides/nitrides, conductive oxides or a doped polysilicon, and may also comprise a stacked structure of the conductive materials described above. A thickness of the bottom electrode layer and the top electrode layer is in a range of 20-200 nm, respectively.

The resistive-switching material layer is a layer of a material having a resistive-switching property, and may comprise a transition metal oxide such as ZnO, HfO₂, TiO₂, ZrO₂, NiO, Ta₂O₅ and so on, a main group metal oxide such as Al₂O₃ and so on, an oxynitride such as SiNₓO_{y} and so on, and an organic material such as poly-p-xylene polymer and so on. A thickness of the resistive-switching material layer is in a range of 10-50 nm.

A method for fabricating the above-mentioned resistive field effect transistor includes following steps:

(1) defining a active region on a semiconductor substrate by shallow trench isolation;

(2) growing a gate dielectric layer;

(3) depositing a stacked control gate layer: firstly, depositing a bottom electrode layer, then depositing a dielectric layer of a resistive-switching material, and depositing a top electrode layer over the resistive-switching material layer deposited, so as to form a stacked gate structure of top electrode/resistive-switching material layer/bottom electrode layer;

(4) forming a gate structure pattern of the device by using a photolithography and an etching method;

(5) forming a sidewall protection structure of the device by using a sidewall process;

(6) forming a doped source/drain structure by further performing ion implantation to the device, and performing a high temperature rapid thermal annealing to activate the impurities;

(7) finally, performing conventional CMOS back-end processes, which include depositing a passivation layer, opening a contact hole, and performing metallization, so as to fabricate the resistive field effect transistor, as shown in FIG. 1.

In the step (2) of the above-mentioned fabrication method, a method for growing the gate dielectric layer may be a method selected from the following methods: a conventional thermal oxidation, a nitrogen-doped thermal oxidation, a chemical vapour deposition and a physical vapour deposition.

In the step (3) of the above-mentioned fabrication method, a method for depositing the stacked control gate layer may be a method selected from the following methods: a direct-current sputtering, a chemical vapour deposition, a reactive sputtering, a chemical synthesis, an atomic layer deposition, a method of direct-current sputtering with thermal oxidation, and a sol-gel method.

In the step (4) of the above-mentioned fabrication method, the etching method may comprise etching the top electrode and the bottom electrode layer by using a wet etching or a dry etching (AME, RIE), and may comprise etching the resistive-switching material layer by using a wet etching or dry etching (RIE, ICP, AME).

The advantages and effects of the present invention are described as follows:

1. The structure adopts a structure of top electrode/resistive-switching material layer/bottom electrode layer as the gate, and by using the property of the resistive-switching material, the gate is transited from high resistance to low resistance under excitation a lower forward voltage. In term of capacitance, the equivalent gate capacitance rapidly increases, so that the threshold voltage of the device is reduced, and a limitation of the subthreshold slope of the conventional MOSFET is broken.

2. The source/drain of the structure adopts the same doping type and concentration, and when compared with the TFET and IMOS devices that generate carriers by using a tunnelling mechanism or an impact ionization mechanism, the device of the present invention has a larger on-state current.

3. Compared with other materials, the memory fabricated with a resistive-switching material has advantages of a rapid speed, a low operation voltage, and a simple process. Herein, the resistive-switching material is adopted in a logic device, so that the ReFET can achieve the transition of the threshold voltage under a low voltage so as to achieve a turn-on of the device, and the ReFET may be suitable for low-voltage and low-power-consumption field.

4. The process of the structure can be easily performed, and may be compatible with the conventional CMOS process.

In short, the structure of the device adopts a structure of top electrode/resistive-switching material layer/bottom electrode layer as the gate, and by using the property of the resistive-switching material, the device achieves an ultra-steep subthreshold slope and the fabrication for manufacturing the device is easy. Compared with the existing methods that break the limitation of the conventional subthreshold slope, the device of the invention has a larger on-current, a lower operation voltage, and a better subthreshold feature, thus it is desirable to be applied in a low-power field, and also, it has a higher practical value.

### BRIEF DESCRIPTION OF THE DRAWINGS

FIG. 1 is a cross section view of a resistive field effect transistor of the invention;

FIG. 2 is a schematic diagram of process steps of growing a gate dielectric layer and depositing a stacked gate layer over a semiconductor substrate;

FIG. 3 is a cross section view of a gate pattern formed after performing a photolithography and an etching method;

FIG. 4 is a cross section view of the device after forming protection sidewalls;

FIG. 5 is a cross section view of the device after forming a source/drain structure by ion implantation;

In which:

1—semiconductor substrate;

2—gate dielectric layer;

3—bottom electrode layer;

4—resistive-switching material layer;

5—top electrode layer;

6—sidewalls;

7—source/drain doping regions.

### DETAILED DESCRIPTION OF THE EMBODIMENTS

The invention will be further described below by examples. It is noted that, these embodiments are disclosed to help further understanding the invention, however, those skilled in the art can appreciate that various changes and modifications may be possible without departing from the spirit and scope of the invention and the following claims. Therefore, the scope protected by the invention is the scope defined by the following claims and is not limited to the contents disclosed by the embodiments.

An embodiment of a fabrication method of the invention includes process steps as shown in FIGS. 2 to 5.

1. An isolation layer for active regions is formed over a bulk silicon substrate 1 having a crystal orientation of (100) by using a shallow trench isolation technology; a gate dielectric layer 2 is then thermally grown, wherein the gate dielectric layer is SiO₂, and has a thickness of 4 nm; a bottom electrode layer 3 is deposited, wherein the bottom electrode layer is TiN, and has a thickness of 20 nm; subsequently a resistive-switching material layer 4 is sputtered, wherein the resistive material layer is Ta₂O₅, and has a thickness of 25 nm; and finally a metal layer of Pt with a thickness of 200 nm is sputtered on the Ta₂O₅ layer as a top electrode 5, as shown in FIG. 2;

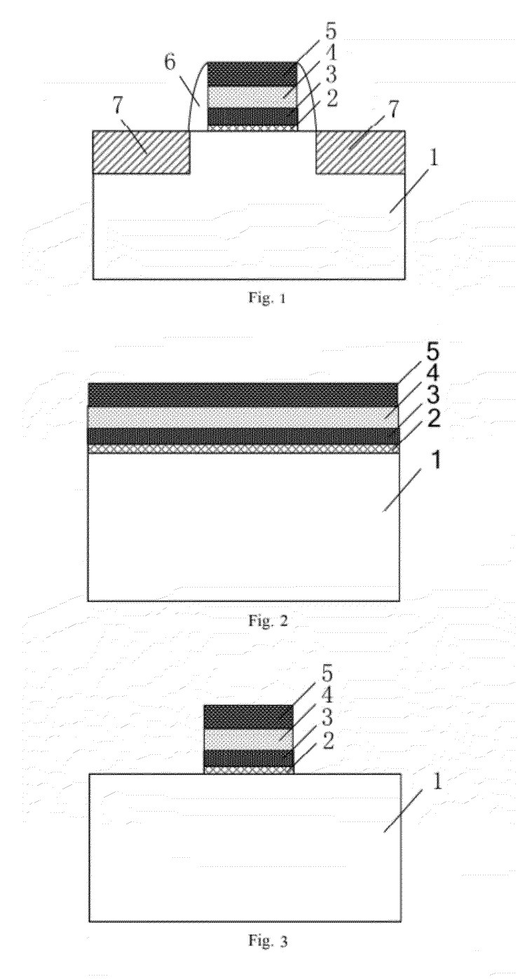

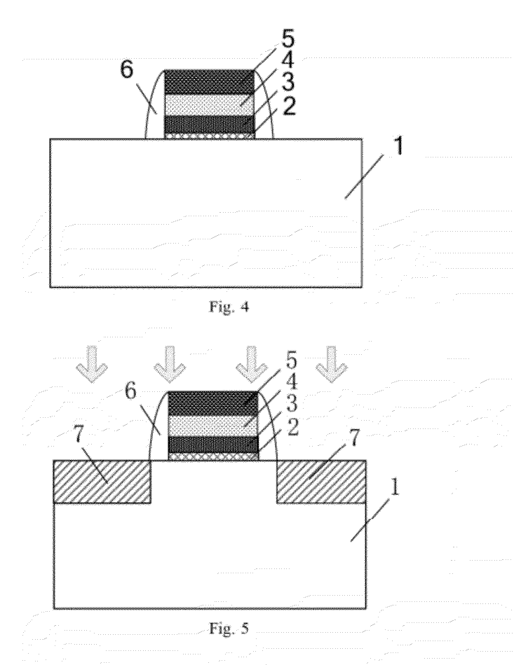

2. Photolithography is performed to form a gate pattern, and a dry etching AME is performed to etch the Pt/Ta₂O₅/TiN stacked gate layer, as shown in FIG. 3

3. An SiO₂ layer with a thickness of 50 nm is deposited by LPCVD method to cover the gate structure, and thereafter, a dry etching is performed to form a gate structure protected by sidewalls 6, as shown in FIG. 4.

4. A source/drain ion implantation is performed, so that a doped source/drain 7 is formed by using a self-aligning effect of the gate, wherein an energy of the ion implantation is 50 KeV, and the implanted impurities are As⁺, as shown in FIG. 5; and a high temperature rapid thermal annealing is performed to activate the impurities.

Finally, conventional CMOS back-end processes are performed, which include depositing a passivation layer, opening a contact hole, and performing metallization, etc., so as to fabricate the above-mentioned resistive field effect transistor.

The present invention has been disclosed by the preferred embodiments as described above, however, it is not intended to limit the present thereby. Those who skilled in the art can appreciate that various changes and modifications may be made with respect to the techincal solutions of the present invention, or equivalent embodiment may be obtained by making equivalent modifications, without departing from the spirit and scope of the invention. Therefore, the scope protected by the invention is the scope defined by the following claims and is not limited to the contents disclosed by the embodiments. Therefore, any simple change, equivalent change and modification to the above-mentioned embodiments according to the techincal essence of the invention without departing from the scope of the invention belongs to the scope of the present invention.

What is claimed is:

1. A resistive field effect transistor, characterized in that, the resistive field effect transistor comprises a control gate electrode layer, a gate dielectric layer, a semiconductor substrate, a doped source region and a doped drain region, wherein the control gate is configured to adopt a stacked gate structure in which a bottom layer or a bottom electrode layer, a middle layer or a resistive-switching material layer, and a top layer or a top electrode layer are sequentially formed.

2. The resistive field effect transistor as claimed in claim 1, characterized in that, a material of the semiconductor substrate includes Si, Ge, SiGe, GaAs or other binary or ternary compound semiconductor of II-VI, III-V and IV-IV groups, silicon on insulator, or germanium on insulator.

3. The resistive field effect transistor as claimed in claim 1, characterized in that, a material of the gate dielectric layer includes SiO₂, Si₃N₄ and a high-K gate dielectric material, and a thickness of the gate dielectric layer is in a range of 1-5 nm.

4. The resistive field effect transistor as claimed in claim 1, characterized in that, the bottom electrode layer and the top electrode layer are various metals including Cu, W, TiN, Pt, Al, etc., a conductive layer including a conductive metal silicide/nitride, a conductive oxide or a doped polysilicon, or a stacked structure of said conductive materials, and a thickness of the bottom electrode layer and the top electrode layer is in a range of 20-200 nm, respectively.

5. The resistive field effect transistor as claimed in claim 1, characterized in that, the resistive-switching material layer comprises a layer of a material having a resistive-switching property, comprising a transition metal oxide including ZnO, HfO₂, TiO₂, ZrO₂, NiO, Ta₂O₅ and so on, a main group metal oxide including Al₂O₃ and so on, an oxynitride including SiN_{X}O_{y} and so on, and an organic material including poly-p-xylene polymer and so on, and a thickness of the resistive-switching material layer is in a range of 10-50 nm.

6. A method for fabricating a resistive field effect transistor, includes following steps:
(1) defining an active region on a semiconductor substrate by shallow trench isolation;
(2) growing a gate dielectric layer;
(3) depositing a stacked control gate layer: firstly, depositing a bottom electrode layer, then depositing a resistive-switching material dielectric layer and depositing a top electrode layer over the resistive-switching material layer deposited, so as to form a stacked gate structure of the top electrode/the resistive-switching material layer/the bottom electrode layer;
(4) forming a gate structure pattern of the device by using a photolithography and an etching method;
(5) forming a sidewall protection structure of the device by using a sidewall process;
(6) forming a doped source/drain structure by further performing ion implantation to the device, and performing a high temperature rapid thermal annealing to activate impurities;
(7) finally, performing conventional CMOS back-end processes, which include depositing a passivation layer, opening a contact hole, and performing metallization, so as to fabricate the resistive field effect transistor as claimed in claim 1.

7. The fabrication method as claimed in claim 6, characterized in that, in the step (2), a method for growing the gate dielectric layer comprises a method selected from following methods: conventional thermal oxidation, nitrogen-doped thermal oxidation, chemical vapour deposition and physical vapour deposition.

8. The fabrication method as claimed in claim 6, characterized in that, in the step (3), a method for depositing the stacked control gate layer comprises a method selected from following methods: direct-current sputtering, chemical vapour deposition, reactive sputtering, chemical synthesis, atomic layer deposition, direct-current sputtering with thermal oxidation, and sol-gel method.

9. The fabrication method as claimed in claim 6, characterized in that, in the step (4), the etching method comprises etching the top electrode and the bottom electrode layer by using AME or RIE method, and etching the resistive-switching material layer by using AME, RIE or ICP method.
